(19) United States
(12) Patent Application Publication
(10) Pub. No.: US 2014/0353020 A1
(43) Pub. Date: Dec. 4, 2014

(54) TOUCH PANEL

(71) Applicant: TIANJIN FUNAYUANCHUANG TECHNOLOGY CO., LTD., Tianjin (CN)

(72) Inventors: CHIH-HAN CHAO, New Taipei (TW); PO-SHENG SHIH, New Taipei (TW); JIA-SHYONG CHENG, New Taipei (TW)

(21) Appl. No.: 13/906,329

(22) Filed: May 30, 2013

(51) Int. Cl. H05K 1/02; H05K 1/03

(52) U.S. Cl. CPC H05K 1/0213; H05K 1/0393; B82B 1/002
USPC 174/258; 174/268; 977/742; 977/932

(57) ABSTRACT

A touch panel defines a touch region and a routing region. The touch panel includes a substrate, a transparent conductive layer, at least one electrode and at least one lead wire. The substrate has a surface and includes a planar part and a folded part extending from the planar part. The transparent conductive layer is located on the surface of the substrate. At least a first part of the transparent conductive layer is located on the planar part and located in the touch region. The at least one electrode is electrically connected to the conductive layer. The at least one lead wire is electrically connected to the at least one electrode in a one-to-one manner. At least part of the at least one lead wire is located on the folded part. The folded part is located in at least part of the routing region.

### BACKGROUND

1. Technical Field

The present disclosure relates to touch panels, particularly to a touch panel based on carbon nanotubes.

2. Discussion of Related Art

Various electronic apparatuses such as mobile phones, car navigation systems, and the like are equipped with optically transparent touch panels applied over display devices such as liquid crystal panels. The electronic apparatus is operated when contact is made with the touch panel corresponding to elements appearing on the display device. A demand thus exists for such touch panels to maximize visibility and reliability in operation. Resistive and capacitive type touch panels are widely applied because of the higher accuracy and low cost of production.

Both the resistance-type or capacitance-type touch panel includes a glass substrate, a transparent conductive layer made of indium tin oxide and a number of lead wires. The lead wires are usually printed on a surface of the glass substrate, and electrically connected with the transparent conductive layer. At least part of the transparent conductive layer defines a touch region having touch function and a routing region for locating the lead wires Because the routing region cannot be touched, the touch panel includes the routing region, which makes a volume of the touch panel larger than the touch region of the touch panel.

What is needed, therefore, is to provide a touch panel, to overcome the above-described shortcomings.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 shows a scanning electron microscope (SEM) image of a carbon nanotube film applied in one embodiment of a touch panel.

FIG. 2 is an unfolded, exploded, isometric view of one embodiment of a touch panel.

FIG. 3 is a folded, isometric view of the touch panel show in FIG. 2.

FIG. 4 is an unfolded, exploded, isometric view of one embodiment of a touch panel.

FIG. 5 is an unfolded and isometric view of the touch panel show in FIG. 4.

FIG. 6 is a folded and isometric view of the touch panel show in FIG. 4.

FIG. 7 is an unfolded, exploded, isometric view of one embodiment of a touch panel.

FIG. 8 is an unfolded and isometric view of the touch panel show in FIG. 7.

FIG. 9 is a folded and isometric view of the touch panel show in FIG. 7.

### DETAILED DESCRIPTION

The disclosure is illustrated by way of example and not by way of limitation in the figures of the accompanying drawings. It should be noted that references to “an” or “one” embodiment in this disclosure are not necessarily to the same embodiment, and such references mean at least one.

A touch panel is provided. The touch panel includes a substrate, a transparent conductive layer, at least one electrode and at least one lead wire. The transparent conductive layer is located on a surface of the substrate. The at least one electrode is electrically connected to the transparent conductive layer. The at least one lead wire is electrically connected to the at least one electrode in a one-to-one manner. The at least one lead wire is configured to electrically connect the at least one electrode with an external circuit. The touch panel defines a touch region and a routing region. The touch region is configured to be touched and viewed to realize the control function. The routing region includes the at least one electrodes and the at least one lead wire, which cannot be touched and viewed to realize the control function. At least part of the transparent conductive layer is located in the touch region, the at least one lead wire is located in the routing region. The substrate has at least one side folded into a fold part. The folded part of the substrate is located in at least part of the routing region. According to a structure of the touch panel or an electronic device using the touch panel, the routing region is at least partly defined on the folded part of the substrate, which can effectively reduce a non-touch area of a touch surface of the touch panel. As such, under the equal touch area of touch surface of the touch panel, the touch surface of the above touch panel can be reduced, therefore, the size of the touch panel can be reduced, and the electronic device using the touch panel can be miniaturized. Wherein, the touch surface is a surface of the touch panel facing to a user, the touch area of the touch surface can display image. The non-touch area of the touch surface cannot be used to display image.

The substrate includes a planar part and the folded part formed by extending from the planar part. At least part of the planar part can be located in the touch region. The folded part can be located on periphery of the planar part. The touch region is defined on the planar part of the substrate. According to the type and apply manner of the touch panel, the transparent conductive layer, the at least one electrode, the at least one lead wire, the touch region and the routing region can be positioned differently from each other.

In one embodiment, all the planar part of the substrate is located in the touch region, and the folded part of the substrate is located in the routing region. Simultaneously, the transparent conductive layer is located on the entire planar part of the substrate, and selectively extends to the folded part of the substrate. All of the at least one routing lead wire and all of the at least one electrode are located on the folded part of the substrate.

In one embodiment, a part of the planar part is located in the touch region, and at least part of the at least one lead wire and at least part of the at least one electrode are located on the other part of the planar part. Namely, the routing region not only covers the folded part, but also covers a part of the planar part. Thus, the transparent conductive layer can only be located on the planar part located in the touch region, or extend to the folded part located in the routing region. Specifically, when the touch panel includes a number of electrodes and lead wires, a part of each electrode can be located on the folded part of the substrate, another part of each electrode can be located on the planar part of the substrate, a part of each lead wire can be located on the folded part of the substrate, and another part of each lead wire can be located on the planar part of the substrate. In one embodiment, the touch panel includes a number of electrodes and lead wires, at least one of the electrodes is entirely located on the folded part of the substrate, the remaining electrodes are located on the plane part of the substrate, at least one of the lead wires is completely located on the folded part of the substrate, and the residual lead wires are located on the plane part of the substrate.

The number of the substrate, the transparent conductive layer, the electrode, and the lead wire are not limited to one, but can be two or more. The number of the electrode and the lead wire can be four or more.

The substrate is transparent and flexible. The substrate is used to support the transparent conductive layer, the at least one electrode, and the at least one lead wire. The substrate can be made of plastic, resin, or any other suitable flexible material, such as polycarbonate (PC), polymethyl methacrylate acrylic (PMMA), polyethylene terephthalate (PET), polyether polysulfones (PES), polyvinyl polychloride (PVC), benzocyclobutenes (BCB), polyesters or acrylic resins. Materials of the substrate are not limited to the above described.

The transparent conductive layer includes a carbon nanotube layer including a number of carbon nanotubes. The carbon nanotubes are substantially oriented along a same direction. A thickness of the carbon nanotube layer can be about 0.5 nanometers (nm) to about 100 micrometers (μm). In one embodiment, the thickness of the carbon nanotube layer is about 100 nm to about 200 nm.

The carbon nanotube layer includes at least one carbon nanotube film. The carbon nanotube film is flexible and can be folded into any shape, because the carbon nanotubes are flexible. The carbon nanotube film is also transparent and electrically conductive. A transparency of the carbon nanotube film can be greater than 85% during visible light region. If the carbon nanotube layer includes a number of carbon nanotube films, the carbon nanotube films can be overlapped with each other or located side by side without space, and the carbon nanotubes in the carbon nanotube films extend substantially along a same direction. The layers of the carbon nanotube film in the carbon nanotube layer are not limited, as long as the carbon nanotube layer can be transparent.

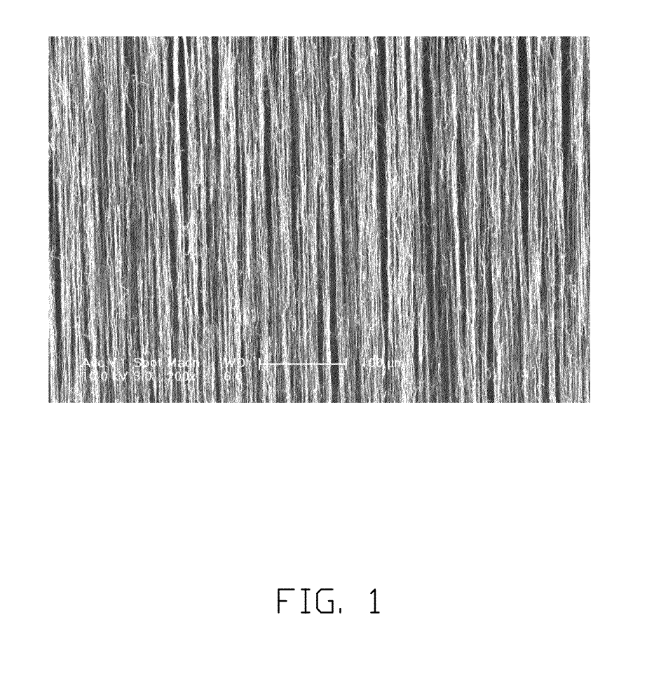

Referring to FIG. 1, the carbon nanotube film includes a number of carbon nanotubes substantially oriented along a same preferred orientation and approximately parallel to each other. The extending directions of the carbon nanotubes are substantially parallel to the surface of the carbon nanotube film. The carbon nanotubes are joined end-to-end by van der Waals attractive force therebetween. The carbon nanotube film is a free-standing structure. The term “free-standing structure” includes, but is not limited to, a structure capable of being supported by itself and does not need a substrate to lie on. For example, the carbon nanotube film can be lifted by one point thereof such as a corner without sustaining damage under its own weight. In this connection, the term “approximately” or “substantially” as used herein means that it is impossible and unnecessary that each of the carbon nanotubes in the carbon nanotube films be exactly parallel to one another, because in the course of fabricating the carbon nanotube film, some factor such as the change of drawing speed and non-uniform drawing force on the carbon nanotube film when the carbon nanotube film is drawn from a carbon nanotube array affects the orientations of the carbon nanotubes.

A film can be drawn from a carbon nanotube array to form the ordered carbon nanotube film. The carbon nanotube film is an electrically anisotropic film. The resistant conductivity of the carbon nanotube film along the extending directions of the carbon nanotubes can be less than the resistant conductivities of the carbon nanotube layer along other directions. Examples of carbon nanotube film are taught by U.S. Pat. No. 7,045,108 to Jiang et al. The carbon nanotube film includes a plurality of successive and oriented carbon nanotubes joined end-to-end by van der Waals attractive force therebetween. The carbon nanotube film is a free-standing film. The carbon nanotube film can be treated with an organic solvent to increase the mechanical strength and toughness of the carbon nanotube film and reduce the coefficient of friction of the carbon nanotube film. A thickness of the carbon nanotube film can range from about 0.5 nm to about 100 μm.

A method of making a carbon nanotube film includes providing an array of carbon nanotubes and pulling out a carbon nanotube film from the array of carbon nanotubes. Pulling can be aided by the use of a tool such as adhesive tape, pliers, tweezers, or other tools allowing multiple carbon nanotubes to be gripped and pulled simultaneously. The carbon nanotube film can be formed by selecting one or more carbon nanotubes having a predetermined width from the array of carbon nanotubes and pulling the carbon nanotubes at a substantially uniform speed to form carbon nanotube segments that are joined end to end to achieve a uniform carbon nanotube film.

The carbon nanotube segments can be selected by using the tool allowing multiple carbon nanotubes to be gripped and pulled simultaneously to contact the array of carbon nanotubes. The pulling direction can be substantially perpendicular to the growing direction of the array of carbon nanotubes.

Specifically, during the pulling process, as the initial carbon nanotube segments are drawn out, other carbon nanotube segments are also drawn out end to end due to van der Waals attractive force between ends of adjacent segments. This process of pulling produces a substantially continuous and uniform carbon nanotube film having a predetermined width.

The at least one electrode is located on a surface of the transparent conductive layer or a surface of the substrate. The at least one electrode is arranged on the periphery of the touch region. A material of the electrode can be metal, carbon nanotube, conductive silver paste, or other conductive material, as long as the material is an electrically conductive material. If the at least one electrode is located on the folded part of the substrate, the material of the at least one electrode can be made of carbon nanotube, conductive silver paste, or other conductive and flexible material. Thus, the electrically conductivity of the at least one electrode almost cannot be affected by the folding of the at least one electrode, or only slightly affected. If the touch panel includes a number of electrodes, the electrodes are spaced and electrically insulated from each other.

One end of each lead wire is electrically connected with one of the at least one electrode, the other end of each lead wire is electrically connected with the external circuit, such as a circuit board. A material of the at least one lead wire is a flexible and electrically conductive material, such as conductive silver paste, conductive polymer, or carbon nanotube. The at least one lead wire can be formed by printing, coating, or layering electrically material on the substrate. It can be understood that the at least one lead wire is electrically connected with the at least one electrode in a one-to-one manner. In one embodiment, the touch panel includes a number of lead wires spaced and electrically insulated from each other. One end of the lead wires is congregated to the same side of the transparent conductive layer and electrically connected with the external circuit.

Other function layers can also be inserted in the touch panel, such as a protective layer, a shield layer.

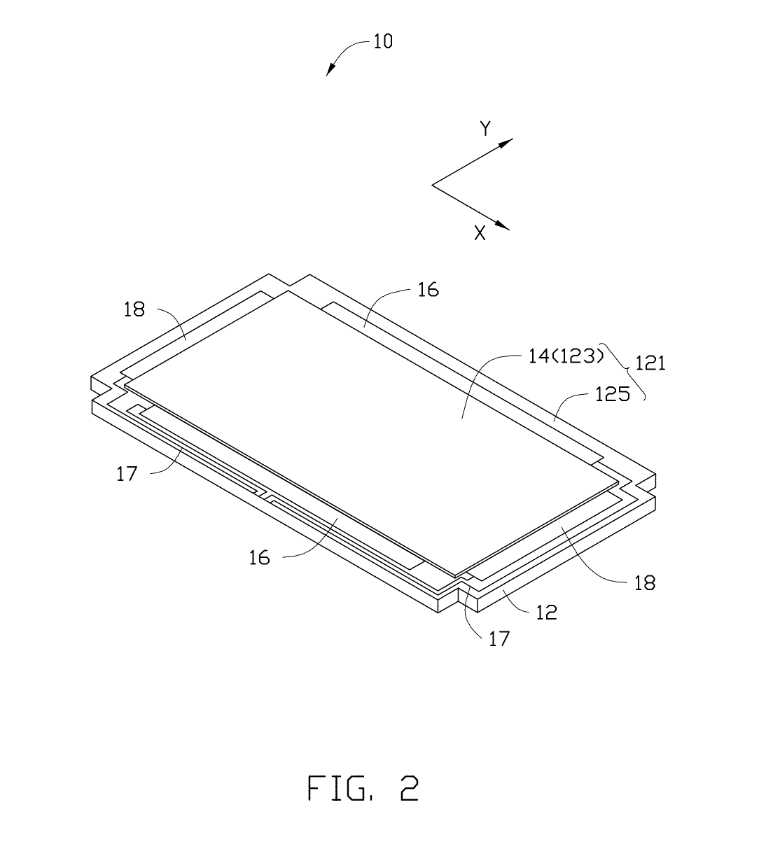

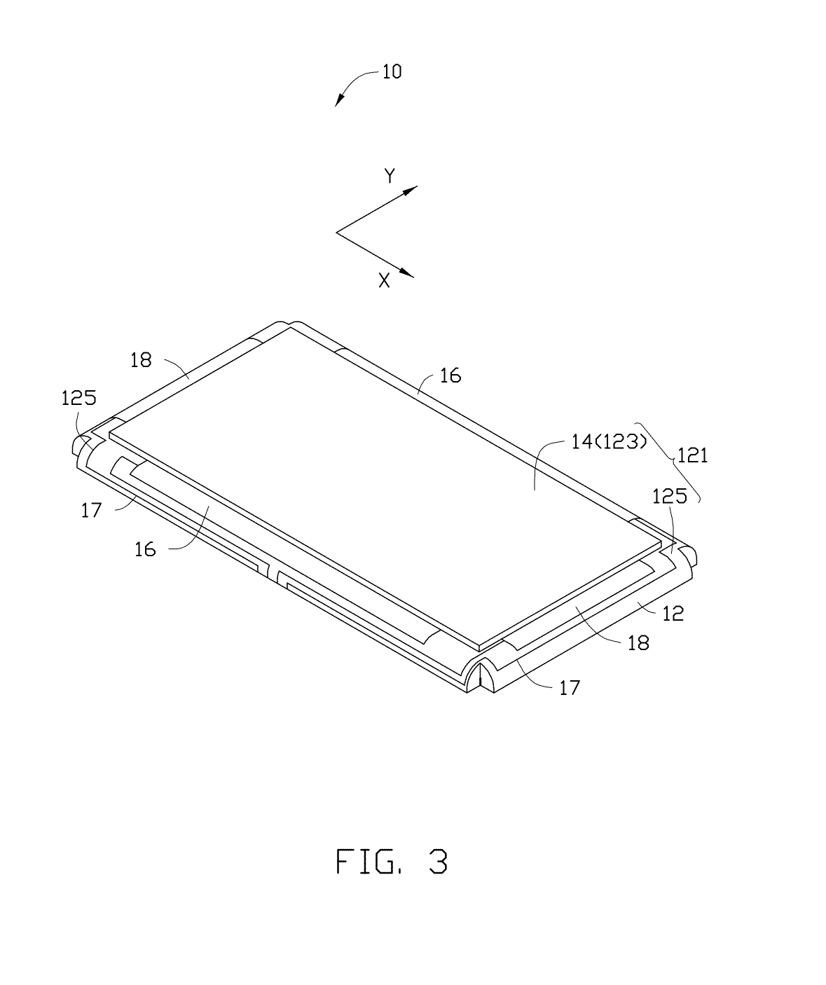

Referring to FIGS. 2 and 3, one embodiment of a capacitance-type touch panel 10 is provided. The touch panel 10 defines a touch region and a routing region, and includes a substrate 12, a transparent conductive layer 14, two first electrodes 16, four lead wires 17, and two second electrodes 18. The substrate 12 includes a surface 121. The transparent conductive layer 14 is placed on the surface 121 of the substrate 12. The first electrodes 16 are spaced from each other along a Y direction and electrically connected to the transparent conductive layer 14. The second electrodes 18 are spaced from each other along an X direction and electrically connected to the transparent conductive layer 14. The X direction is substantially perpendicular to the Y direction. Thus, an equipotential plane is formed on the transparent conductive layer 14. The two first electrodes 16 and the two second electrodes 18 are electrically connected with an external circuit (not shown) through the four lead wires 17. The four lead wires 17 are congregated to one side of the surface 121 of the substrate 12. The entire transparent conductive layer 14 is located in the touch region, and the four lead wires 17 are located in the routing region.

Specifically, the substrate 12 consists of a planar part 123 and a folded part 125. An angle defined by the planar part 123 and the folded part 125 is about 90 degrees. The planar part 123 is located in the center of the surface 121 of the substrate 12. The folded part 125 surrounds the planar part 123. The entire planar part 123 is located in the touch region, and the entire transparent conductive layer 14 is located on the entire planar part 123. The substrate 12 is folded along the periphery of the transparent conductive layer 14 to make the folded part 125 located around the transparent conductive layer 14. The entire folded part 125 is located in the routing region. The two first electrodes 16, the two second electrodes 18, and the four lead wires 17 are located on the folded part 125. Therefore, the entire display surface capable of display images of the touch panel 10 is in the touch region, and not located in the routing region. The touch panel 10 has no border in the display surface. The volume of the touch panel 10 is small. The touch panel 10 can be easily applied in a micro-scaled electronic device. In the present embodiment, the substrate 12 is made of PC. The transparent conductive layer 14 is a single carbon nanotube film, and the carbon nanotubes in the transparent conductive layer 14 are substantially oriented along the X direction. The two first electrodes 16, the two second electrodes 18, and the four lead wires 17 are formed by printing silver paste on the surface 121 of the substrate 12.

The number of the first and second electrodes 16, 18 can be one, or the touch panel 10 can include a plurality of first electrodes 16 or a plurality of second electrodes 18. The X direction can be crossed with but not perpendicular to the Y direction.

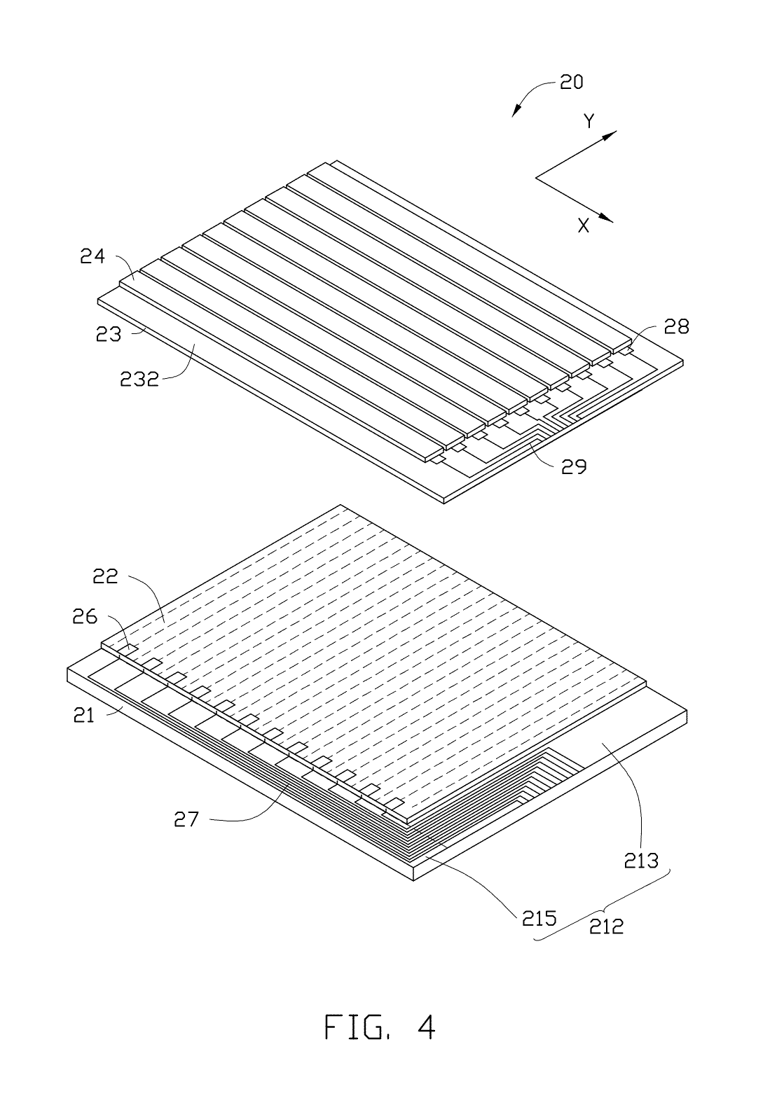

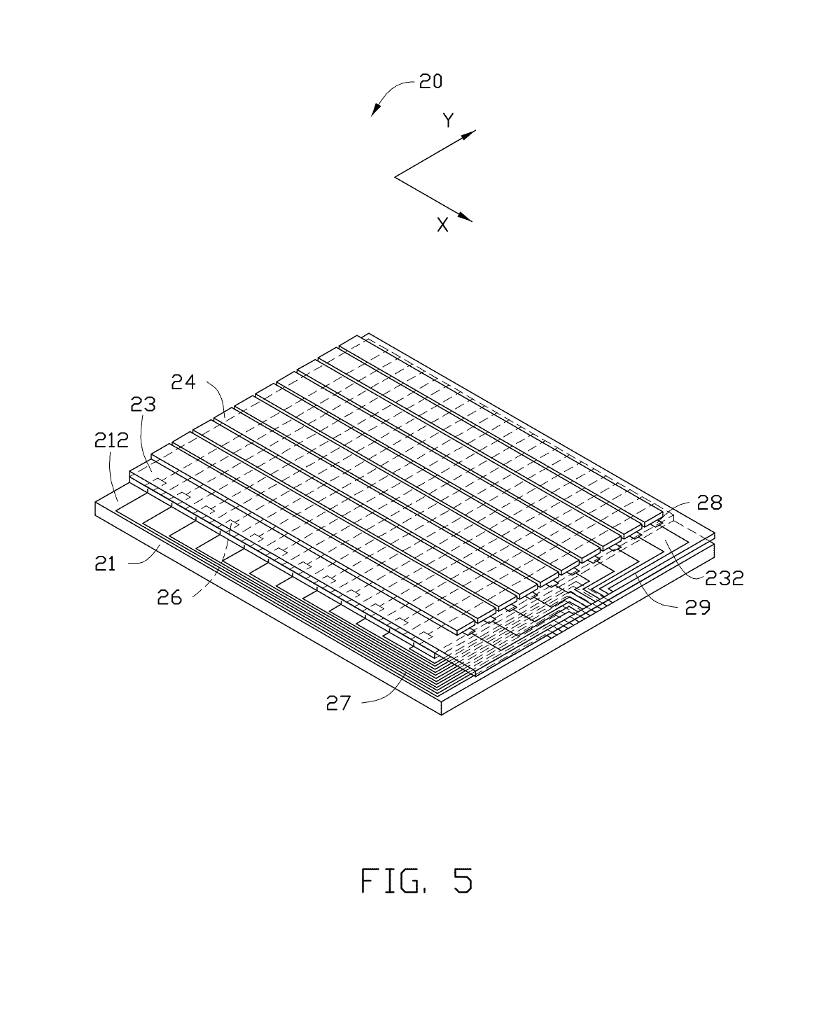

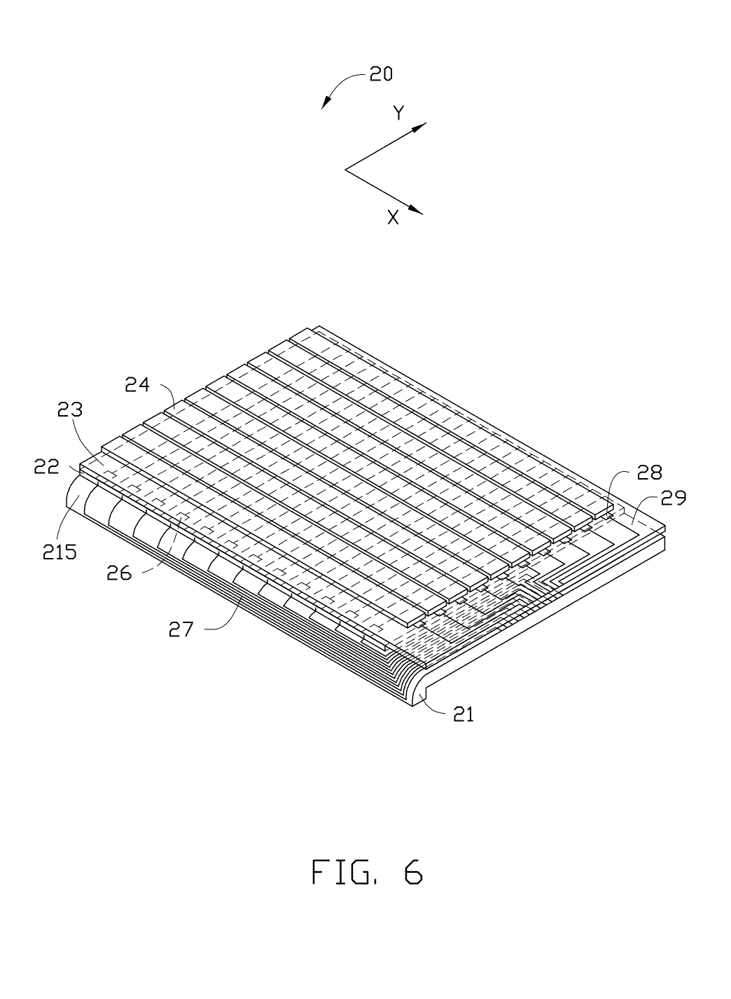

Referring to FIGS. 4-6, one embodiment of a touch panel 20 is provided. The touch panel 20 is a multi-touch capacitance-type touch panel which includes a first substrate 21, a first transparent conductive layer 22, a second substrate 23, a second transparent conductive layer 24, a number of first electrodes 26, a number of first lead wires 27, a number of second electrodes 28, and a number of second lead wires 29. The second transparent conductive layer 24 is located near the display surface of the touch panel 20. The second conductive layer 24, the second substrate 23, the first transparent conductive layer 22, and the first substrate 21 are overlapped with each other in sequence. The first electrodes 26 are electrically connected to the first transparent conductive layer 22 and separately located on a side of the first transparent conductive layer 22 substantially parallel to an X direction. The first electrodes 26 are electrically connected to an external circuit through the first lead wires 27. The second electrodes 28 are electrically connected to the second transparent conductive layer 24 and separately located on a side of the second transparent conductive layer 24 substantially parallel to a Y direction. The second electrodes 28 are electrically connected to the external circuit through the second lead wires 29. The touch panel defines a touch region and a routing region. A region, where the first transparent conductive layer 22 is overlapped with the second transparent conductive layer 24, defines the touch region. The first lead wires 27 and the second lead wires 29 are located in the routing region.

The first substrate 21 has a surface 212 and includes a planar part 213 and a folded part 215 extending from the planar part 213. The folded part 215 is located at one side of the planar part 213 substantially parallel to the X direction. Parts of the first lead wires 27 are located on the folded part 215. The touch region covers part of the planar part 213. The routing region covers the folded part 215 and the other part of the planar part 213. The first substrate 21 is made of PC.

The first transparent conductive layer 22 is located on the surface 212 of the first substrate, and entirely located on the planar part 213. The first transparent conductive layer 22 is a single carbon nanotube film including a number of carbon nanotubes substantially arranged along a same direction. The carbon nanotubes in the first transparent conductive layer 22 substantially extend along the Y direction and are joined end-to-end along the Y direction. The resistant conductivity of the first transparent conductive layer 22 along the Y direction is smaller than the resistant conductivities of the transparent conductive layer 212 along other directions. The X direction is substantially parallel to the surface of the first transparent conductive layer 22 and perpendicular to the Y direction. The resistant conductivity of the first transparent conductive layer along the Y direction is the smaller than the resistant conductivities of the first transparent conductive layer along the X directions.

The first transparent conductive layer 22 can be considered as a plurality of spaced conductive strips. The first transparent conductive layer 22 can have excellent electrical conductivity along the Y direction, and the first electrodes 26 are spaced from each other along the X direction. Each conductive strip extends along the Y direction. The conductive strips are electrically connected to the first electrodes 26 one by one. The first electrodes 26 are formed by printing silver paste on the first transparent conductive layer 22. The first transparent conductive layer 22 can also be a carbon nanotube film treated with an etching or laser method. The carbon nanotube film is treated with the laser method to form a number of laser cutting lines on the surface of the carbon nanotube film. Thus, the anisotropic property of the carbon nanotube film is improved.

The first lead wires 27 are electrically connected to the first electrodes 26 in a one-to-one manner. The first lead wires 27 are congregated to the same side of the first transparent conductive layer 22 and electrically connected to the external circuit. The first lead wires 27 are spaced from each other. The first lead wires 27 are formed by printing silver paste on the surface 212 of the first substrate 21. The first lead wires 27 extend crossing over the folded part 215 to converge at one side of the first substrate 21 substantially parallel to the Y direction. As such, parts of the first lead wires 27 substantially parallel to the X direction are located on the folded part 215, and the other parts of the first lead wires 27 substantially parallel to the Y direction are located on the planar part 213.

The second substrate 23 has a surface 232 away from the surface 212 of the first substrate. The second substrate 23 is a planar structure made of glass. The second substrate 23 does not include a folded part. The second substrate 23 can be made of other stiff materials, such as glass or quartz. The second substrate 23 can also be made of flexible materials such that the second substrate 23 can include a folded part.

The second transparent conductive layer 24 is located on the surface 232 of the second substrate 23 and includes a number of patterned conductive structures (not labeled). The conductive structures are spaced from each other, and extend along the X direction. The patterned conductive structures are substantially parallel to each other along the Y direction. Electrically conductive directions of the second transparent conductive layer 24 are substantially perpendicular to the direction of the first transparent conductive layer 22 having a minimal resistant conductivity. In one embodiment, the second transparent conductive layer 24 is a patterned ITO film with a number of strip-shaped conductive structures. The electrically conductive directions of the strip-shaped conductive structures are substantially perpendicular to the carbon nanotubes extending directions in the first transparent conductive layer 22.

The material of the second transparent conductive layer 24 can be the same as that of the first conductive layer 22 made of transparent carbon nanotube film.

The second electrodes 28 are spaced from each other along the Y direction, and are electrically connected to the conductive structures in a one-to-one manner. Each second electrode 218 extends along the X direction. Materials of the second electrodes 28 are the same as that of the first electrodes 26.

The second lead wires 29 are electrically connected to the second electrodes 28 in a one-to-one manner. The second lead wires 29 are congregated to the same side of the second transparent conductive layer 24 and electrically connected to the external circuit connected with the first lead wires 27. The second lead wires 29 are spaced from each other. The second lead wires 29 are formed by printing silver paste on the surface 232 of the second substrate 23. The second lead wires 29 are not folded and are converged at one side of the second substrate 23 substantially parallel to the Y direction.

The first electrodes 26 can also be located on two opposite sides of the first transparent conductive layer 22. The second electrodes 28 can also be located on two opposite sides of the second transparent conductive layer 24. The touch panel 20 can also include only one first electrode 26 and a number of second electrodes 28, or includes only one second electrode 28 and a number of first electrodes 26.

The second substrate 23 separates the first transparent conductive layer 22 and the second transparent conductive layer 24. The conductive strips of the first transparent conductive layer 22 are intercrossed with the conductive structures of the second transparent conductive layer 24 to form a plurality of intercrossed positions. A capacitance can be formed between each of the plurality of intercrossed positions. The capacitance connects with an outer electrical circuit by one of the first electrodes 26 and one of the second electrodes 28. When a finger or other touch tools touch a point close to one or more of the intercrossed positions, the capacitance formed between the one or more of the intercrossed positions will change. The outer electrical circuit can detect the change of the capacitance. Therefore, the point can be detected.

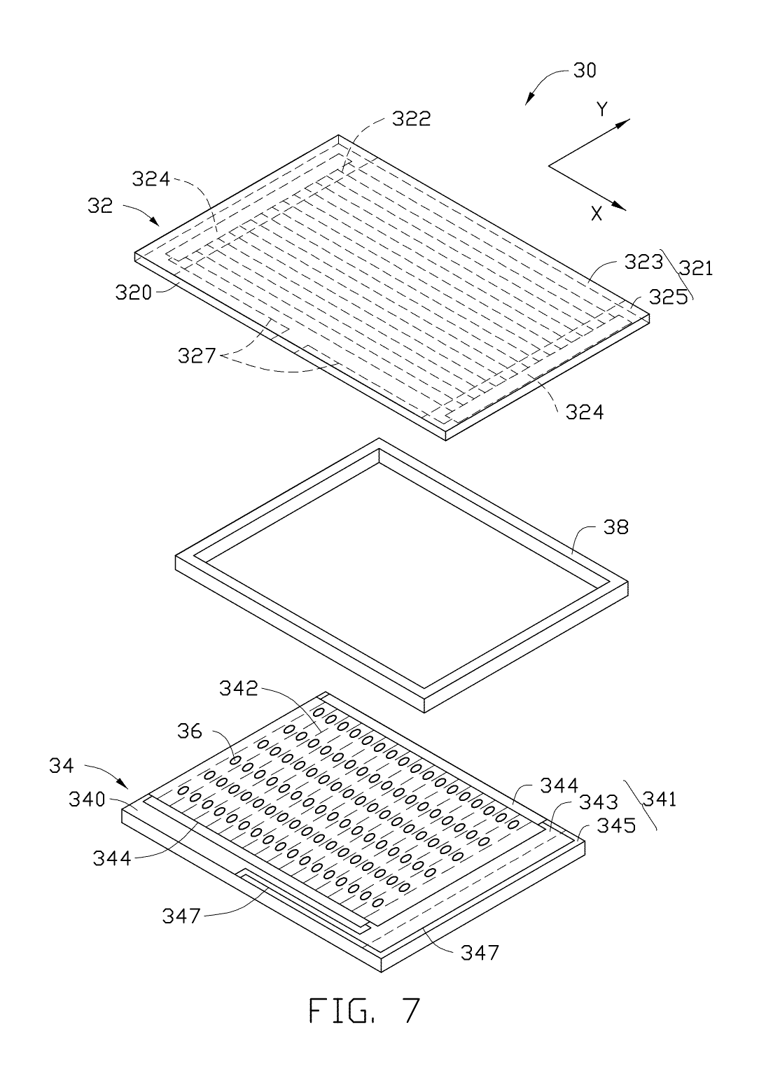

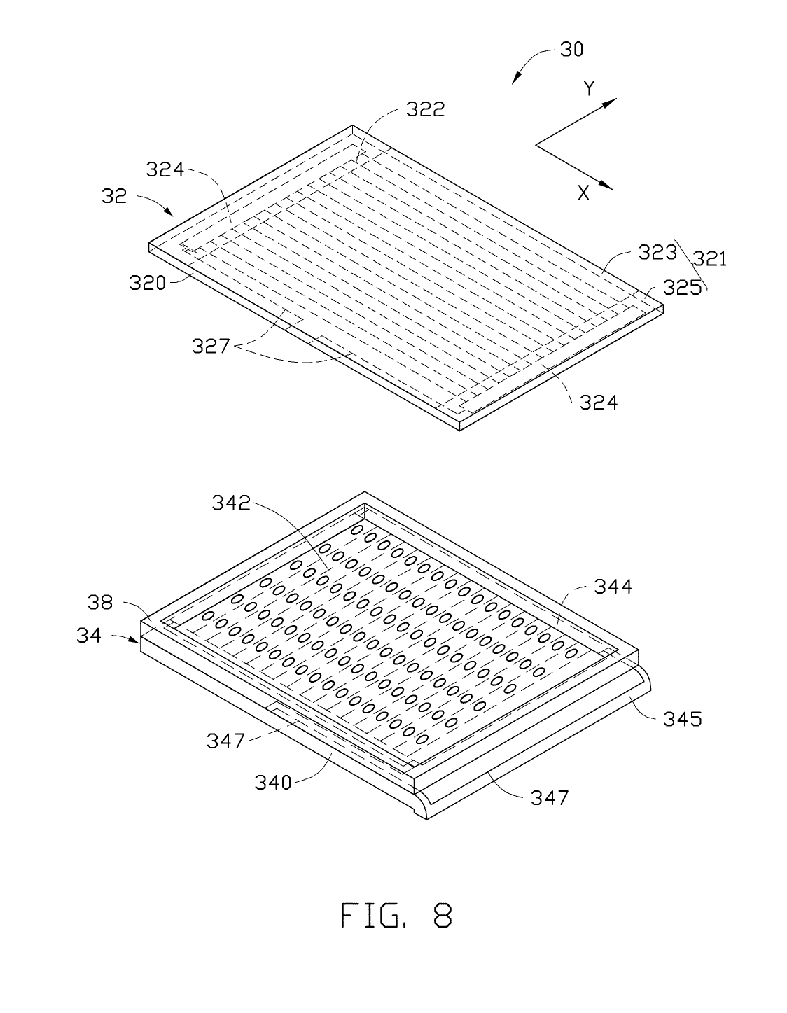

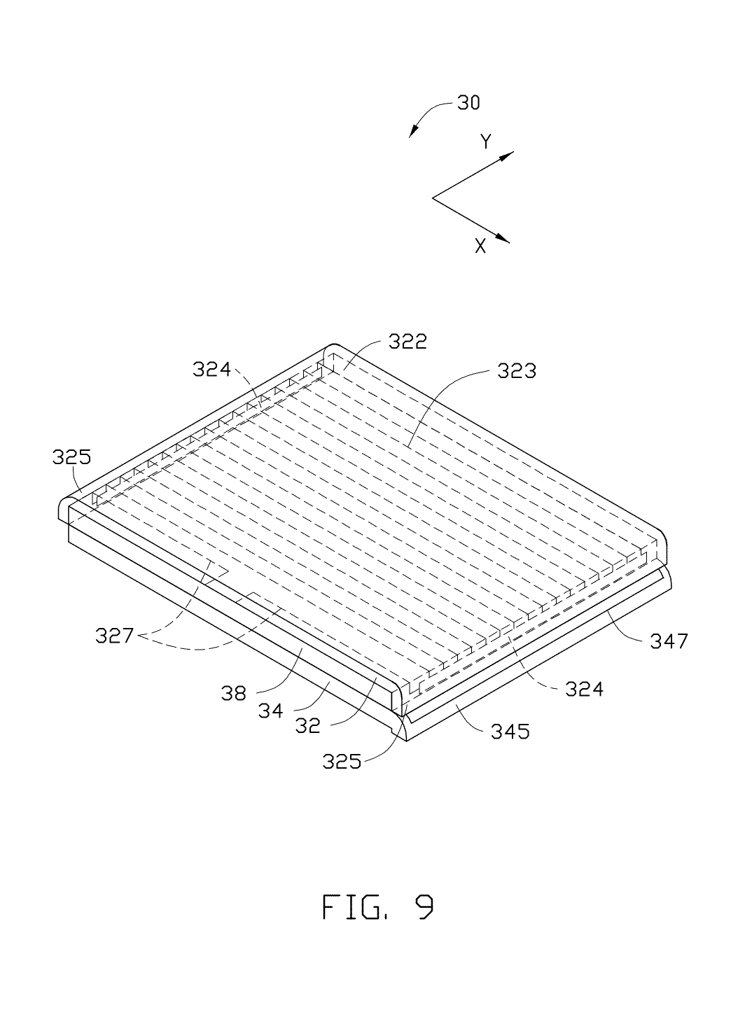

Referring to FIGS. 7-9, one embodiment of a touch panel 30 is provided. The touch panel 30 is a resistance-type touch panel. The touch panel 30 includes a first electrode plate 32, a second electrode plate 34 facing the first electrode plate 32, a plurality of dot spacers 36 and an insulated frame 38. The dot spacers 36 and the insulated layer 134 are located between the first electrode plate 32 and the second electrode plate 34.

The first electrode plate 32 includes a first substrate 320, a first transparent conductive layer 322 located on a surface 321 of the first substrate 320, two first electrodes 324, and two first lead wires 327. The first substrate 320 includes a planar part 323 and two folded parts 325 extending from the planar part 323. The folded parts 325 are located at two opposite sides of the planar part 323 substantially parallel to a Y direction. Parts of the first lead wires 327 are located on the folded part 215. A larger part of the first transparent conductive layer 322 is located on the planar part 323, and a smaller part of the first transparent conductive layer 322 is located on the folded part 325. The two first electrodes 324 are located on the first transparent conductive layer 322 applied on the folded part 325. The two first electrodes 324 are arranged at two opposite sides of the first conductive layer 322 substantially parallel to an X direction. The two first electrodes 324 are electrically connected to the first transparent conductive layer 322. The two first electrodes 324 are electrically connected to an external circuit through the two first lead wires 327. The first lead wires 327 are separately located on the surface 321 of the first substrate 320 and at the periphery of the first transparent conductive layer 322. Specifically, parts of the two first lead wires 327 are located on the planar part 323, the other parts are located on the two folded parts 325.

The second electrode plate 34 is spaced from the first electrode 32, and includes a second substrate 340, a second transparent conductive layer 342 located on a surface 341 of the second substrate 340, two second electrodes 344 and two second lead wires 347. The surface 341 of the second substrate 340 faces the surface 321 of the first substrate 320. The second substrate 340 includes a planar part 343 facing the planar part 323 of the first substrate 320, and a folded part 345 extending from the planar part 343. The folded part 325 is located at one side of the planar part 343 substantially parallel to the Y direction. The second transparent conductive layer 342 is located on the planar part 323 and faces the first transparent conductive layer 322. A space between the first and second transparent conductive layers 322, 342 is about 2 μm to about 10 μm. The two second electrodes 344 are separately located on two opposite sides of the second conductive layer 342 substantially parallel to the Y direction. The two second electrodes 344 are electrically connected to the second transparent conductive layer 342. The two second electrodes 344 are electrically connected to the external circuit through the two second lead wires 347. One of the second lead wires 347 is located on the planar part 343, and the other second electrode 347 is located on the planar part 343 and the folded part 345. A region of the touch panel 30, where the first transparent conductive 322 is overlapped with the second transparent conductive layer 324, defines a touch region. The planar part 323 of the first substrate 320 and a part of the planar part 343 of the second substrate 340 are located in the touch region. The first lead wires 327 and the second lead wires 347 are located in a routing region defined by the touch panel 30. The folded part 325 of the first substrate 320, another part of the planar part 343 of the second substrate 340 and a part of the folded part 345 of the second substrate 340 are located in the routing region. The X direction is crossed with the Y direction. In one embodiment, the X direction is substantially perpendicular to the Y direction.

The first substrate 320 can be a transparent and flexible film or a transparent and flexible plate. The materials of the second substrate 340 can be the same as the first substrate 320 with flexible property. The second substrate 340 can also be made of transparent and rigid material. In one embodiment, the first and second substrates 320, 340 are made of PET with a thickness about 2 millimeters.

Both the first transparent conductive layer 322 and the second transparent conductive layer 342 are made of a single carbon nanotube film. The carbon nanotubes in the first transparent conductive layer 322 are joined end-to-end and oriented along the X direction. The carbon nanotubes in the second transparent conductive layer 342 are joined end-to-end and oriented along the Y direction. One of the first transparent conductive layer 322 and the second transparent conductive layer 342 can be an indium tin oxide (ITO) layer, an antimony tin oxide (ATO) layer, or other stiff material layer.

The two first electrodes 324 and the two second electrodes 344 are made of electrically conductive materials, such as metal, conductive polymer, carbon nanotubes, or any other electrically conductive materials. In one embodiment, the materials of the two first electrodes 324 and the two second electrodes 344 are silver paste.

The two first lead wires 327 are electrically connected to the two first electrodes 324 in a one-to-one manner. The first lead wires 327 are congregated to the same side of the first substrate 320 and electrically connected to the external circuit. The two second lead wires 347 are electrically connected to the two second electrodes 344 in a one-to-one manner. The second lead wires 347 are congregated to the same side of the second substrate 340 and electrically connected to the external circuit connected with the first lead wires 327. Specifically, the first lead wires 327 are located on the planar part 323 and congregated to one side of the planar part 323 of the first substrate 320 substantially parallel to the X direction. One of the second lead wires 347 is located on one side of the planar part 343 of the second substrate 340 substantially parallel to the X direction, the other one extends from the folded part 345 of the second substrate 340 to the side of the planar part 343 of the second substrate 340 substantially parallel to the X direction. The first lead wires 327 and the second lead wires 347 are formed by printing silver paste on the surface 212 of the first substrate 21.

The transparent dot spacers 36 are separately located on the second transparent conductive layer 342 and spaced from the first transparent conductive layer 322. The insulated frame 38 is mounted between the first substrate 320 and the second substrate 340. The transparent dot spacers 36 and the insulated frame 38 can be made of, for example, insulated resin or any other suitable insulated material. Insulation between the first electrode plate 32 and the second electrode plate 34 can be provided by the transparent dot spacers 36 and the insulated frame 38. The transparent dot spacers 36 are optional, especially if the touch panel 30 is relatively small. They serve as supports given the size of the span and the strength of the first electrode plate 32.

The amounts of the first electrodes 324, the first lead wire 327, the second electrode 344, and the second lead wire in the touch panel 30 are more than two, and the touch panel 30 can be a multi-point touch panel.

It is to be understood that the above-described embodiment is intended to illustrate rather than limit the disclosure. Variations may be made to the embodiment without departing from the spirit of the disclosure as claimed. The above-described embodiments are intended to illustrate the scope of the disclosure and not restricted to the scope of the disclosure.

It is also to be understood that the above description and the claims drawn to a method may include some indication in reference to certain steps. However, the indication used is only to be viewed for identification purposes and not as a suggestion as to an order for the steps.

What is claimed is:

1. A touch panel defining a touch region and a routing region, comprising:
a substrate having a surface and comprising a planar part and a folded part extending from the planar part;
a transparent conductive layer located on the surface of the substrate, wherein at least a first part of the transparent conductive layer is located on the planar part and the planar part is located in the touch region;
at least one electrode electrically connected to the conductive layer; and
at least one lead wire electrically connected to the at least one electrode in a one-to-one manner, wherein at least part of the at least one lead wire is located on the folded part, and the folded part is located in at least part of the routing region.

2. The touch panel of claim 1, wherein at least part of each of the at least one lead wire is located on the folded part.

3. The touch panel of claim 2, wherein at least part of each of the at least one electrode is located on the folded part.

4. The touch panel of claim 3, wherein at least a second part of the transparent conductive layer is located on the folded part.

5. The touch panel of claim 3, wherein at least one electrode and at least one lead wire are entirely located on the folded part.

6. The touch panel of claim 5, wherein the transparent conductive layer is entirely located on the planar part, and the entire planar part is located in the touch region.

7. The touch panel of claim 1, wherein the at least one lead wire comprises a plurality of lead wires congregated to the same side of the substrate, a part of the plurality of lead wires are spacedly located on the planar part, and another part of the plurality of lead wires are spacedly located on the folded part.

8. The touch panel of claim 7, wherein the at least one electrode comprises two electrodes separately located on two opposite sides of the transparent conductive layer.

9. The touch panel of claim 7, wherein the at least one electrode comprises a plurality of electrodes separately located on two opposite sides of the transparent conductive layer.

10. The touch panel of claim 1, wherein a material of the substrate is a flexible material.

11. The touch panel of claim 10, wherein the flexible material is selected from the group consisting of polycarbonate, polymethyl methacrylate acrylic, polyethylene terephthalate, polyether polysulfones, polyvinyl polychloride, benzocyclobutenes, polyesters, and acrylic resins.

12. The touch panel of claim 1, wherein the transparent conductive layer comprises a carbon nanotube layer comprising a plurality of carbon nanotubes substantially oriented along the same direction.

13. The touch panel of claim 12, wherein the plurality of carbon nanotubes are joined end-to-end along the same direction by van der Waals force.

14. The touch panel of claim 1, wherein a material of the at least one lead wire is silver paste or carbon nanotube.

15. A touch panel defining a touch region and a routing region, comprising:
at least one substrate comprising a planar part and at least one folded part extending from the planar part;
at least one transparent conductive layer located on the at least one substrate, wherein the at least one transparent conductive layer located on the planar part is located in the touch region;
at least one lead wire electrically connected to the at least one transparent conductive layer, wherein the at least part of the at least one lead wire is located on the at least one folded part, and the at least one folded part is located in the routing region.

16. The touch panel of claim 15, wherein the at least one substrate is a single substrate comprising the planar part and a plurality of folded parts located on a periphery of the planar part.

17. The touch panel of claim 16, further comprising a plurality of electrode, wherein the at least one transparent conductive layer is a single transparent conductive layer, the plurality of electrodes are electrically connected to the single transparent conductive layer, the at least one lead wire is a plurality of lead wires, and the plurality of lead wires are electrically connected to the plurality of electrodes.

18. The touch panel of claim 17, wherein the plurality of electrodes are separately located on one side of the transparent conductive layer.

19. The touch panel of claim 17, wherein the plurality of electrodes are separately located on two opposite sides of the transparent conductive layer.

20. The touch panel of claim 17, wherein the plurality of lead wires are located on at least part of the plurality of folded parts, and the plurality of electrodes are located on the at least part of the plurality of folded parts.
